(19) United States
(12) Patent Application Publication
(10) Pub. No.: US 2025/0228112 A1
(43) Pub. Date: Jul. 10, 2025

(54) DISPLAY DEVICE, METHOD OF MANUFACTURING THE SAME AND ELECTRONIC DEVICE INCLUDING THE SAME

(71) Applicant: Samsung Display Co., Ltd., Yongin-Si (KR)

(72) Inventor: HO YUN BYUN, Yongin-si (KR)

(21) Appl. No.: 18/976,329

(22) Filed: Dec. 11, 2024

(30) Foreign Application Priority Data
Jan. 10, 2024 (KR) 10-2024-0004021

(51) Int. Cl. H10K 59/80; H10K 59/65

(52) U.S. Cl. CPC H10K 59/8791; H10K 59/65

(57) ABSTRACT

A display device includes a display panel including at least one light-emitting element, an optical functional layer disposed on the display panel, a window layer disposed on the optical functional layer, a first adhesive layer disposed between the optical functional layer and the window layer, and including a first contact surface inclined toward the optical functional layer in a direction from a center of the optical functional layer to an edge of the optical functional layer, and a second adhesive layer disposed between the first adhesive layer and the window layer, and including a second contact surface inclined toward the window layer in the direction from the edge of the optical functional layer toward an outer edge of the display panel.

### CROSS-REFERENCE TO RELATED APPLICATION(S)

This application claims priority under 35 U.S.C. § 119 to Korean Patent Application No. 10-2024-0004021, filed on Jan. 10, 2024, which is hereby incorporated by reference for all purposes as if fully set forth herein.

### BACKGROUND

### 1. Field

Embodiments relate to a display device and a method of manufacturing the same. More particularly, the embodiments relate to the display device with an adhesive layer and the method of manufacturing the same.

### 2. Description of the Related Art

The display device may include a display panel and a window layer. Pixels may be arranged on the display panel, and images are displayed using the pixels. A video may be displayed to users through the window layer. The window layer may include a film that protects the display panel. An adhesive layer may be disposed between the display panel and the window layer. An adhesive material forming the adhesive layer may be ejected in liquid form through an inkjet process and then cured through a curing process.

### SUMMARY

Embodiments of the present disclosure provide a display device with improved display quality.

Embodiments of the present disclosure provide a method of manufacturing the display device.

A display device according to an embodiment may include a display panel including at least one light-emitting element, an optical functional layer disposed on the display panel, a window layer disposed on the optical functional layer, a first adhesive layer disposed between the optical functional layer and the window layer, and including a first contact surface inclined toward the optical functional layer in a direction from a center of the optical functional layer to an edge of the optical functional layer, and a second adhesive layer disposed between the first adhesive layer and the window layer, and including a second contact surface inclined toward the window layer in a direction from the edge of the optical functional layer toward an outer edge of the display device.

In an embodiment, the second contact surface of the second adhesive layer may extend from the first contact surface of the first adhesive layer to the window layer and pass over the end of the optical functional layer.

In an embodiment, at least one hole extending through the optical functional layer may be defined in the optical functional layer, the first adhesive layer may further include a third contact surface inclined toward the optical functional layer in a direction toward a boundary of the hole, and the second adhesive layer may further include a fourth contact surface inclined toward the window layer in a direction from the boundary of the hole.

In an embodiment, the fourth contact surface of the second adhesive layer may extend from the third contact surface to the window layer and may pass over the boundary of the hole.

In an embodiment, the third contact surface and the fourth contact surface may be adjacent to the hole.

In an embodiment, the first adhesive layer and the second adhesive layer may include a same material.

In an embodiment, the first adhesive layer may include a material different from the second adhesive layer.

In an embodiment, the second adhesive layer may include a light blocking material.

In an embodiment, a thickness of the second adhesive layer may be about 50 μm or less.

In an embodiment, the display device may further include a light blocking layer overlapping the second adhesive layer, and a width of the second adhesive layer is greater than a width of the light blocking layer.

A method of manufacturing a display device according to an embodiment may include applying a first adhesive material on an optical functional layer, forming a first cured layer including a first inclined surface on the optical functional layer by curing the first adhesive material, applying a second adhesive material on a window layer, forming a second cured layer including a second inclined surface on the window layer by curing the second adhesive material, and bonding the optical functional layer and the window layer by bringing the first cured layer and the second cured layer into contact with each other.

In an embodiment, each of the first adhesive material and the second adhesive material may have a thixotropic index calculated using an equation:
thixotropic index=η0.5/η5.0, where η0.5 refers to a viscosity at 25° C., 0.5 rpm and η5.0 refers to a viscosity at 25° C., 5.0 rpm, and a thixotropic index of the first adhesive material is smaller than a thixotropic index of the second adhesive material.

In an embodiment, the thixotropic index of the first adhesive material may be about 1.5 or less, and the thixotropic index of the second adhesive material may be about 4.0 or more.

In an embodiment, the second adhesive material may include a light blocking material, and the applying the second adhesive material may be performed by an electro hydrodynamic dispensing process.

In an embodiment, a modulus of the first cured layer may be larger than a modulus of the second cured layer.

In an embodiment, the modulus of the first cured layer may be about 0.05 Mpa or less, and the modulus of the second cured layer may be about 0.02 Mpa or less.

In an embodiment, a viscosity of the first cured layer may be smaller than a viscosity of the second cured layer.

In an embodiment, a viscosity of the first adhesive material may be about 50 cP or less, the viscosity of the first cured layer may be about 5,000,000 cP or less, and the viscosity of the second cured layer may be about 1,000,000 cP or less.

In an embodiment, a first inclined angle between the first inclined surface and the optical functional layer may be smaller than a second inclined angle between the second inclined surface and the window layer.

In an embodiment, the method may further include forming a light blocking layer by applying a light blocking material on the window layer, and in the applying the second adhesive material, the second adhesive material is applied to a position where the light blocking layer is formed.

An electronic device according to an embodiment may include a display device and a power supply configured to provide power to the display device. The display device may include a display panel including at least one light-emitting element, an optical functional layer disposed on the display panel, a window layer disposed on the optical functional layer, a first adhesive layer disposed between the optical functional layer and the window layer, and including a first contact surface inclined toward the optical functional layer in a direction from a center of the optical functional layer to an edge of the optical functional layer, and a second adhesive layer disposed between the first adhesive layer and the window layer, and including a second contact surface inclined toward the window layer in a direction from the edge of the optical functional layer toward an outer edge of the display device.

A display device according to embodiments of the present disclosure may include a display panel, an optical functional layer disposed on the display panel, a window layer disposed on the optical functional layer, a first adhesive layer disposed between the optical functional layer and the window layer, and including a first contact surface inclined toward the optical functional layer in a direction from a center of the optical functional layer to an edge of the optical functional layer, and a second adhesive layer disposed between the first adhesive layer and the window layer, and including a second contact surface inclined toward the window layer in the direction from the edge of the optical functional layer toward an outer edge of the display device. Accordingly, by filling a gap between the first adhesive layer and the window layer with the second adhesive layer, a bonding strength between the window layer and the optical functional layer may be improved. Accordingly, a durability of the display device may be improved.

In addition, the display device may include a light blocking layer overlapping a portion of the first contact surface of the first adhesive layer and disposed on the second adhesive layer. The second adhesive layer may overlap a portion where the first adhesive layer is spaced apart from the light blocking layer. Accordingly, components disposed under the window layer may be prevented from being visible to the user, and a light blocking effect of the display device may be improved.

In a method of manufacturing the display device according to embodiments of the present disclosure, the method may include applying a first adhesive material on the optical functional layer, forming a first cured layer using the first adhesive material, applying a second adhesive material on the window layer, and forming a second cured layer using the second adhesive material, and bonding the optical functional layer and the window layer so that the first cured layer and the second cured layer are in contact with each other. Accordingly, reducing a number of curing process for the first adhesive layer may facilitate the bonding between the window layer and the optical functional layer. Therefore, the durability of the display device may be further improved.

### BRIEF DESCRIPTION OF THE DRAWINGS

The above and other features of the present disclosure will be more clearly understood with reference to the following detailed description and the accompanying drawings.

FIG. 1 is a plan view illustrating a display device according to an embodiment of the present disclosure.

FIG. 2 is a cross-sectional view of the display device taken along a line I-I′ of FIG. 1.

FIG. 3 is an enlarged cross-sectional view illustrating an area A of FIG. 2.

FIG. 4 is a cross-sectional view of the display device taken along a line II-II′ of FIG. 1.

FIG. 5 is a plan view illustrating a process before a first adhesive layer is applied on an optical functional layer.

FIG. 6 is a cross-sectional view illustrating a process of applying a first adhesive material to a cross-section of the optical functional layer taken along a line III-III′ of FIG. 5.

FIG. 7 is an enlarged cross-sectional view of a portion of a first area of FIG. 6.

FIG. 8 is an enlarged cross-sectional view of a first hole area of FIG. 6.

FIG. 9 illustrates a process of forming a first cured layer in the first area.

FIG. 10 illustrates a process of forming the first cured layer in the first hole area.

FIG. 11 is a plan view illustrating a process before a second adhesive layer is applied on a window layer.

FIG. 12 is a cross-sectional view illustrating a process of applying a second adhesive material to a cross-section of the window layer taken along a line IV-IV′ of FIG. 11.

FIG. 13 illustrates a second preliminary adhesive layer in a second area.

FIG. 14 illustrates the second preliminary adhesive layer PAM2 in a second hole area.

FIG. 15 illustrates a process of forming a second cured layer in the second area.

FIG. 16 illustrates a process of forming the second cured layer in the second hole area.

FIGS. 17 and 18 illustrate a process of bonding the optical function layer and the window layer such that the first cured layer and the second cured layer are in contact with each other.

FIGS. 19 and 20 illustrate the change of the shape of the first cured layer and the second cured layer during a process of bonding the optical functional layer and the window layer.

FIG. 21 illustrates a process of forming a display panel under the optical functional layer and forming a protective layer on the window layer.

FIG. 22 is a cross-sectional view illustrating another example of the display device taken along a line I-I′ of FIG. 1.

FIG. 23 is a cross-sectional view illustrating a method of manufacturing a second adhesive layer of FIG. 22.

FIG. 24 is a block diagram illustrating an electronic device according to an embodiment.

### DETAILED DESCRIPTION OF THE EMBODIMENTS

Hereinafter, display devices in accordance with embodiments of the present disclosure will be described in more detail with reference to the accompanying drawings. The same reference numerals are used for the same components in the drawings, and redundant descriptions of the same components will be omitted.

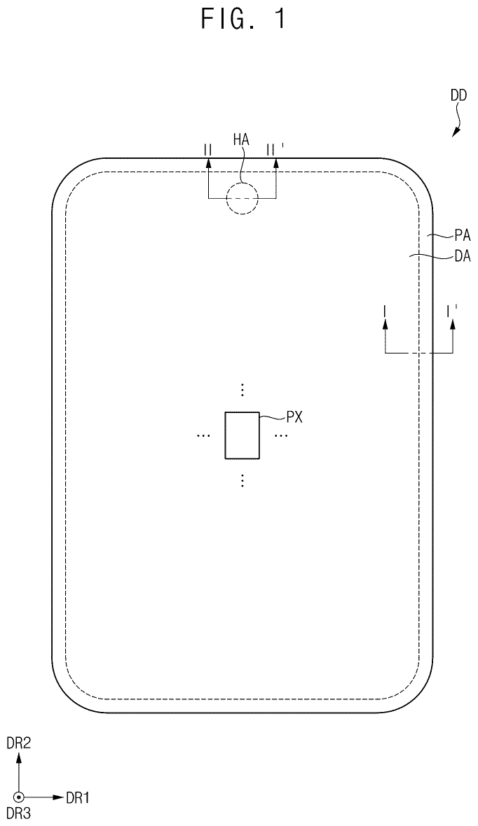

FIG. 1 is a plan view illustrating a display device according to an embodiment of the present disclosure.

Referring to FIG. 1, a display device DD according to an embodiment of the present disclosure may include a display area DA, a peripheral area PA, and a hole area HA.

In this specification, a plane may be defined as a first direction DR1 and a second direction DR2. For example, the second direction DR2 may be perpendicular to the first direction DR1. In addition, the third direction DR3 may be perpendicular to the plane.

The display area DA may be defined as an area where images are displayed by generating light or adjusting the transmittance of light provided from an external light source. In addition, the display area DA may include at least one pixel PX comprising a plurality of sub-pixels which emit lights with different colors. For example, the plurality of sub-pixels may include a red sub-pixel which emits red light, a green sub-pixel which emits green light, and a blue sub-pixel which emits blue light.

The peripheral area PA may be defined as an area which does not display an image. The peripheral area PA may be located around the display area DA. For example, the peripheral area PA may surround at least a portion of the display area DA.

A driver may be disposed in the peripheral area PA. For example, the driver may be a component driving the pixel PX. The driver may include a data driver, a gate driver, a light emission driver, a power voltage generator, a timing controller, or the like. The pixel PX may emit the light based on a signal applied from the driver.

A hole area HA may be disposed in the display area DA. In an embodiment, the hole area HA may be disposed in an upper center of the display area DA. But the present disclosure may not be limited thereto. The hole area HA may be disposed in an upper left of the display area DA, or the hole area HA may be disposed in an upper right of the display area DA.

In an embodiment, the hole area HA may have a circular shape in a plan view. But the present disclosure may not be limited thereto. The hole area HA may have a different shape than the circular shape in a plan view. For example, the hole area HA may have a polygonal shape in a plan view.

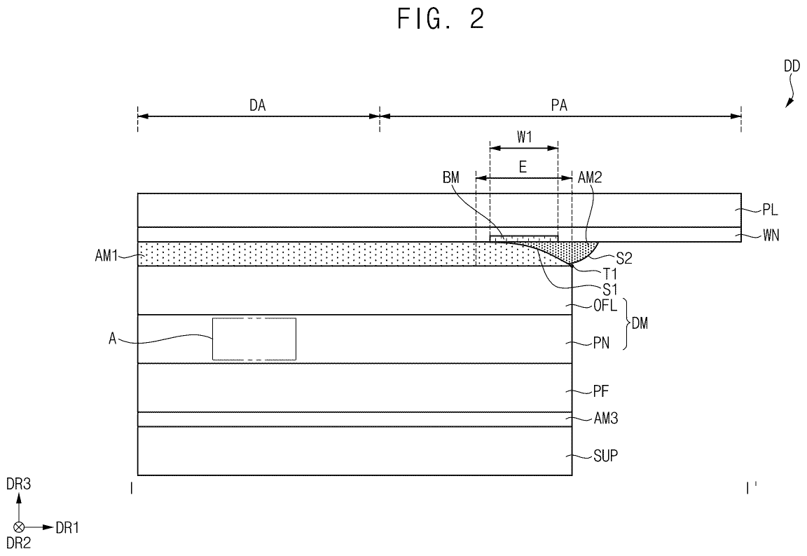

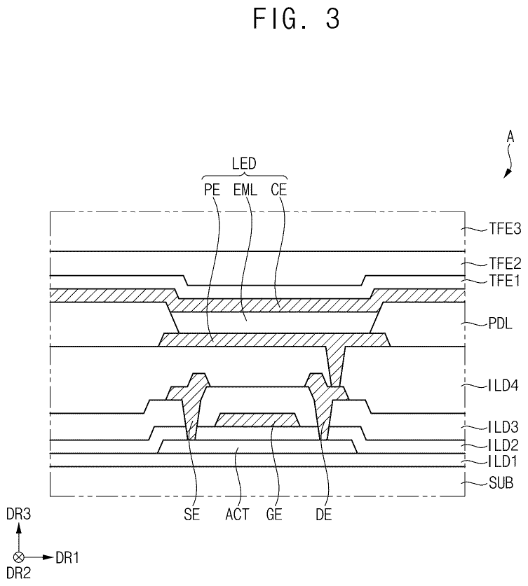

FIG. 2 is a cross-sectional view of the display device taken along a line I-I′ of FIG. 1. FIG. 3 is an enlarged cross-sectional view illustrating an area A of FIG. 2. For example, FIG. 3 is a cross-sectional view illustrating a cross-section of a display panel PN included in a display module DM.

Referring to FIGS. 2 and 3, the display device DD may include the display module DM, a first adhesive layer AM1, a second adhesive layer AM2, a window layer WN, a light blocking layer BM, a protective layer PL, a support member SUP, a protective film PF, and a third adhesive layer AM3.

The display module DM may include the display panel PN and an optical functional layer OFL.

The display panel PN may be disposed in the display area DA and a portion of the peripheral area PA. The display panel PN may include a substrate SUB, a first insulation layer ILD1, an active layer ACT, a second insulation layer ILD2, a gate electrode GE, a third insulation layer ILD3, a source electrode SE, a drain electrode DE, a fourth insulation layer ILD4, a pixel electrode PE, a pixel define layer PDL, a light-emitting layer EML, a common electrode CE, a first encapsulation layer TFE1, a second encapsulation layer TFE2, and a third encapsulation layer TFE3.

The substrate SUB may be a transparent insulating substrate. For example, the substrate SUB may include a glass, a quartz, a plastic, or the like. These may be used alone or in combination with each other.

The first insulation layer ILD1 may be disposed on the substrate SUB. The first insulation layer ILD1 may prevent impurities from diffusing from the substrate SUB to the active pattern ACT.

The first insulation layer ILD1 may include an inorganic insulating material. The inorganic insulating material may include a silicon nitride, a silicon oxide, a silicon oxynitride, or the like. These may be used alone or in combination with each other.

The active layer ACT may be disposed on the first insulation layer ILD1. The active layer ACT may include an amorphous silicon, a polycrystalline silicon, or a semiconductor oxide. The active layer ACT may include a source region SR, a drain region DR, and channel region CR disposed between the source region SR and the drain region DR which are doped with impurities.

The second insulation layer ILD2 may be disposed on the first insulation layer ILD1. The second insulation layer ILD2 may cover the active layer ACT disposed on the first insulation layer ILD1 and the first insulating layer ILD1. The second insulation layer ILD2 may have a substantially uniform thickness along a profile of the active layer ACT. However, the present disclosure may not be limited thereto. The second insulation layer ILD2 may sufficiently cover the active layer ACT and may have a substantially flat upper surface without creating a step around the active layer ACT.

The second insulation layer ILD2 may include an inorganic insulating material. The inorganic insulating material may include a silicon nitride, a silicon oxide, a silicon oxynitride, or the like. These may be used alone or in combination with each other.

The gate electrode GE may be disposed on the second insulation layer ILD2. The gate electrode GE may overlap the channel region CR of the active layer ACT. The gate electrode GE may include a metal, an alloy, a conductive metal oxide, a conductive metal nitride, a transparent conductive material, or the like. These may be used alone or in a combination with each other.

The third insulation layer ILD3 may be disposed on the second insulation layer ILD2. The third insulation layer ILD3 may cover the gate electrode GE disposed on the second insulation layer ILD2 and the second insulation layer ILD2. The third insulation layer ILD3 may have a substantially uniform thickness along a profile of the gate electrode GE. However, the present disclosure may not be limited thereto. The third insulation layer ILD3 may sufficiently cover the gate electrode GE and may have a substantially flat upper surface without creating a step around the gate electrode GE.

The source electrode SE and the drain electrode DE may be disposed on the third insulation layer ILD3. The source electrode SE and the drain electrode DE may be in contact with the active layer ACT through a contact hole extending through the second insulation layer ILD2 and the third insulation layer ILD3. Each of the source electrode SE and the drain electrode DE may include a metal, an alloy, a conductive metal oxide, a conductive metal nitride, a transparent conductive material, or the like. These may be used alone or in a combination with each other. The active layer ACT, the gate electrode GE, the source electrode SE, and the drain electrode DE may form a transistor.

The fourth insulation layer ILD4 may be disposed on the third insulation layer ILD3. The fourth insulation layer ILD4 may have a substantially flat upper surface. The fourth insulation layer ILD4 may include an organic insulating material like a polyimide (PI). In an embodiment, an opening exposing a portion of an upper surface of the drain electrode DE may be defined in the fourth insulation layer ILD4. Or, the opening defined in the fourth insulation layer ILD4 may expose a portion of an upper surface of the source electrode SE.

The pixel electrode PE may be disposed on the fourth insulation layer ILD4. In an embodiment, the pixel electrode PE may be in contact with the drain electrode DE through the opening. Or, the pixel electrode PE may be in contact with the source electrode SE through the opening. The pixel electrode PE may include a metal, an alloy, a conductive metal oxide, a conductive metal nitride, a transparent conductive material, or the like. These may be used alone or in a combination with each other. For example, the pixel electrode PE may include a silver (Ag) and an indium tin oxide (ITO).

The pixel define layer PDL may be disposed on the fourth insulation layer ILD4. The pixel define layer PDL may cover the pixel electrode PE partially. In addition, the pixel define layer PDL may include an opening exposing at least a portion of the pixel electrode PE. For example, a center of the pixel electrode PE may directly contact with the light-emitting layer EML through the opening of pixel define layer PDL, and the pixel define layer PDL may cover an edge of the pixel electrode PE. The pixel define layer PDL and the fourth insulation layer ILD4 may include a same material. For example, the pixel define layer PDL may include an organic insulating material like a polyimide (PI).

The light-emitting layer EML may be disposed on a portion of the pixel define layer PDL. The light-emitting layer EML may be disposed on the pixel electrode PE exposed by the opening of the pixel define layer PDL. The light-emitting layer EML may include an organic light-emitting material. The organic light-emitting material may include a low molecular weight organic compounds or a high molecular weight organic compounds. However, the present disclosure may not be limited thereto. The light-emitting layer EML may include a quantum dot, or the like.

The common electrode CE may be disposed on the light-emitting layer EML. The common electrode CE may include a metal, an alloy, a conductive metal oxide, a conductive metal nitride, a transparent conductive material, or the like. For example, the common electrode CE may include an aluminum (Al), a platinum (Pt), a silver (Ag), a magnesium (Mg), a gold (Au), a chromium (Cr), a tungsten (W), a titanium (Ti), or the like. These may be used alone or in a combination with each other. The pixel electrode PE, the light-emitting layer EML, and the common electrode CE may form a light-emitting element LED.

The first encapsulation layer TFE1 may be disposed on the common electrode CE. The first encapsulation layer TFE1 may cover the light-emitting element LED. The first encapsulation layer TFE1 may have a substantially uniform thickness along a profile of the common electrode CE.

The second encapsulation layer TFE2 may be disposed on the first encapsulation layer TFE1. The second encapsulation layer TFE2 may have a substantially flat upper surface without creating a step around the first encapsulation layer TFE1.

The third encapsulation layer TFE3 may be disposed on the second encapsulation layer TFE2. The third encapsulation layer TFE3 may have a substantially uniform thickness and have a substantially flat upper surface. The first, second, and third encapsulation layer TFE1, TFE2, and TFE3 may protect the light-emitting element LED from outside impurities by encapsulating the display area DA.

The optical functional layer OFL may be disposed on the display panel PN, and perform an optical function to control light. The optical functional layer OFL may be a polarization layer.

If the optical functional layer OFL is the polarization layer, the optical functional layer OFL may be disposed on the display panel PN. The optical functional layer OFL may be disposed in the display area DA and a portion of the peripheral area PA. The optical functional layer OFL may polarize light entering from the outside into the display panel PN. The optical functional layer OFL may be stretched in one direction. A stretching direction of the optical functional layer OFL may be an absorption axis, and a direction perpendicular to the stretching direction may be a transmission axis.

The display device DD of FIG. 1 may include a structure in which the polarization layer is removed. In a such case, the optical functional layer OFL may serve as a layer performing the optical function excluding the polarizing layer. For example, the optical functional layer OFL may include a color filter. However, the present disclosure may not be limited thereto.

The window layer WN may be disposed on the optical functional layer OFL. The window layer WN may be disposed over the display area DA and the peripheral area PA. The window layer WN may extend further beyond an end T1 of the optical functional layer OFL toward an outside of the display device DD. Accordingly, a portion of the window layer WN may not overlap the optical function layer OFL in a plan view.

The window layer WN may be an ultrathin glass (UTG). For example, the window layer WN may include a soda-lime glass, an alkali aluminosilicate glass, a borosilicate glass, a lithium aluminosilicate glass, or the like. These may be used alone or in combination with each other. However, the window layer WN of the present disclosure may not be limited thereto and may include various materials such as a plastic.

In an embodiment, the light blocking layer BM may be disposed on the window layer WN. For example, the light blocking layer BM may be disposed in a groove penetrating a portion of the window layer WN. However, the present disclosure may not be limited thereto. The light blocking layer BM may be disposed on one side of the window layer WN. Or, the light blocking layer BM may be disposed within the protective layer PL.

The light blocking layer BM may be disposed in the peripheral area PA. The light blocking layer BM may block a light. Accordingly, the light blocking layer BM may prevent components disposed under the light blocking layer BM (e.g., metal layers in the display panel PN) from being visible to an user.

The first adhesive layer AM1 and the second adhesive layer AM2 may be disposed between the optical functional layer OFL and the window layer WN. For example, the first adhesive layer AM1 and the second adhesive layer AM2 may attach the optical functional layer OFL to the window layer WN.

The first adhesive layer AM1 may be disposed between the optical functional layer OFL and the window layer WN. The first adhesive layer AM1 may entirely cover the optical functional layer OFL. The optical function layer OFL may define an edge area E adjacent to the end T1 of the optical functional layer OFL. For example, the edge area E may be defined as an area where the optical functional layer OFL overlaps a first contact surface S1 of the first adhesive layer AM1. The edge area E may be disposed in the peripheral area PA.

The first adhesive layer AM1 may include the first contact surface S1 having a slope at the edge area E of the optical functional layer OFL. In an embodiment, the first contact surface S1 may incline toward the optical functional layer OFL in a direction from a center of the optical functional layer OFL to the end T1 of the optical functional layer OFL. For example, the first contact surface S1 may extend with the slope in a direction away from an outer edge of the display device DD of FIG. 1 from a point where the first contact surface S1 meets the optical functional layer OFL.

In an embodiment, the first adhesive layer AM1 may include an optically clear adhesive resin (OCR). However, the present disclosure may not be limited thereto.

The second adhesive layer AM2 may be disposed between the first adhesive layer AM1 and the window layer WN. The second adhesive layer AM2 may overlap the light blocking layer BM disposed in the window layer WN. In an embodiment, a width of the second adhesive layer AM2 may be greater than a width of the light blocking layer BM. However, the present disclosure may not be limited thereto. If the light blocking layer BM does not entirely overlap the first adhesive layer AM1, the second adhesive layer AM2 may overlap a portion of the light blocking layer BM which is spaced apart from the first contact surface S1. More particularly, if the light blocking layer BM does not extend from an overlapping portion with the first contact surface S1 to the end T1 of the optical function layer OFL, the second adhesive layer AM2 may cover a portion of the light blocking layer BM which is spaced apart from the first adhesive layer AM1. Accordingly, the components disposed under the window layer WN (e.g., metal layers in the display panel PN) may be concealed from the user, thus enhancing a light blocking effect of the display device DD of FIG. 1.

The second adhesive layer AM2 may include a second contact surface S2. In an embodiment, the second contact surface S2 may be inclined toward the window layer WN in a direction from the end T1 of the optical function layer OFL toward the outer edge of the display device DD. For example, the second contact surface S2 may extend with a slope toward the outer edge of the display device DD of FIG. 1 from a point where the second contact surface S2 is meets the first contact surface S1.

In an embodiment, the second contact surface S2 extends from the first contact surface S1 of the first adhesive layer AM1 to the window layer WN and passes over the end T1 of the optical function layer OFL. In other words, in a plane defined by the first direction DR1 and the second direction DR2, the second contact surface S2 may protrude from the end T1 of the optical functional layer OFL toward the outer edge of the display device DD of FIG. 1. As the second contact surface S2 protrudes from the end T1 of the display device DD toward the outer edge of the display device DD, the second adhesive layer AM2 may overlap a portion of the first adhesive layer AM1 which is spaced apart from the light blocking layer BM. Accordingly, the components disposed under the window layer WN (e.g., metal layers in the display panel PN) may be concealed from the user, thus enhancing the light blocking effect of the display device DD.

In an embodiment, the second adhesive layer AM2 and the first adhesive layer AM1 may include a same material. For example, the second adhesive layer AM2 may include an optically clear adhesive resin (OCR). However, the present disclosure may not be limited thereto.

The protective layer PL may be disposed on the window layer WN. The protective layer PL may be disposed on the display area DA and the peripheral area PA. The protective layer PL may extend toward the outer edge of the display device DD from the end T1 of the optical functional layer OFL like the window layer WN. Accordingly, a portion of the protective layer may not overlap the optical functional layer OFL in a plan view.

In an embodiment, the protective layer PL may include a transparent polymer film. For example, the transparent polymer film may include a polyethylene terephthalate (PET), a polyethylene naphthalate (PEN), a polyether sulfone (PES), a polyimide (PI), a polyarylate (PAR), a polycarbonate (PC), a polymethyl methacrylate (PMMA), or the like. These may be used in alone or combination with each other.

The support member SUP may support other components (e.g., the protective film PF, the display panel PN, or the like) and may be disposed on a lower portion of the display device DD. The support member SUP may include a metal, a glass, or the like.

The protective film PF may be disposed on the support member SUP. The protective film PF may include a polymer material. For example, the polymer material may include a polyimide PI, a polyethylene terephthalate (PET), a polycarbonate (PC), a poly sulfone (PSF), a poly methyl methacrylate (PMMA), or the like. These may be used in alone or combination with each other.

The third adhesive layer AM3 may disposed between the protective film PF and the support member SUP. For example, the third adhesive layer AM3 may attach the protective film PF to the support member SUP. The third adhesive layer AM3 may include a pressure sensitive adhesive (PSA), an optically clear adhesive (OCA), an optically clear resin (OCR), or the like. These may be used in alone or combination with each other.

As described above, the display device DD according to embodiments of the present disclosure may include the first adhesive layer AM1 including the first contact surface S1 inclined toward the optical functional layer OFL in the direction from the center of the optical functional layer OFL to the edge T1 of the optical functional layer OFL and the second adhesive layer AM2 disposed between the first adhesive layer AM1 and the window layer WN, and including the second contact surface S2 inclined toward the window layer WN in the direction from the edge T1 of the optical functional layer OFL toward an outer edge of the display device DD. Accordingly, by filling a gap between the first adhesive layer AM1 and the window layer WN with the second adhesive layer AM2, a bonding strength between the window layer WN and the optical functional layer OFL may be improved. Accordingly, the durability of the display device DD may be improved.

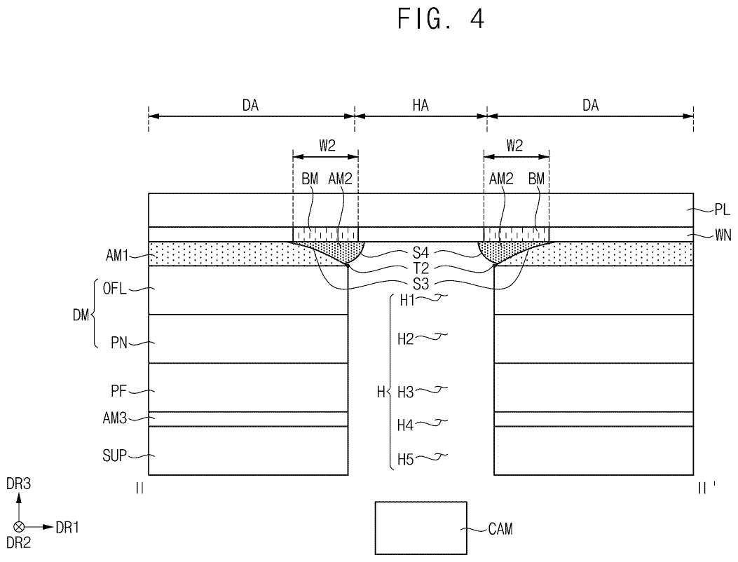

FIG. 4 is a cross-sectional view of the display device taken along a line II-II′ of FIG. 1. For example, FIG. 4 is a cross-sectional view of the display device taken along the hole area HA and a portion of the display area DA around the hole area HA.

Referring to FIG. 4, first, second, third, fourth, and fifth holes H1, H2, H3, H4, and H5 may be defined in the hole area HA.

The first hole H1 extending through the optical functional layer OFL in the third direction DR3 may be defined in the optical functional layer OFL. The first adhesive layer AM1 may include a third contact surface S3 inclined toward the optical functional layer OFL in a direction toward a boundary T2 of the first hole H1. For example, the third contact surface S3 may extend with a slope in a direction away from the first hole H1 from a point where the third contact surface S3 meets the optical functional layer OFL.

The second adhesive layer AM2 may include a fourth contact surface S4 inclined toward the window layer WN in the direction from the boundary T2 of the first hole H1. For example, the fourth contact surface S4 surrounding the first hole H1 may be inclined in a direction toward the first hole H1. More particularly, the fourth contact surface S4 may extend with a slope toward the first hole H1 from a point where the fourth contact surface S4 meets the third contact surface S3. In an embodiment, the fourth contact surface S4 of the second adhesive layer AM2 may extend from the third contact surface S3 of the first adhesive layer AM1 to the window layer WN and pass over the boundary T2 of the first hole H1.

That is, in a plane defined by the first direction DR1 and the second direction DR2, the fourth contact surface S4 may protrude from the boundary T2 of the first hole H1 to a center of the first hole H1. As the fourth contact surface S4 protrudes from the boundary T2 of the first hole H1 toward the center of the first hole H1, the second adhesive layer AM2 may overlap a portion of the first adhesive layer AM1 which is spaced apart from the light blocking layer BM. Accordingly, the components disposed under the window layer WN (e.g., metal layers within the display panel PN) may not be visible to the user, and the light blocking effect of the display device DD may be improved.

The light blocking layer BM may be disposed in a portion of the hole area HA and a portion of the display area DA adjacent to the hole area HA and may be disposed within the window layer WN. For example, the light blocking layer BM may be disposed in a portion of the hole area HA and a portion of the display area DA adjacent to the hole area HA and may be disposed within a groove penetrating a portion of the window layer WN. However, the present disclosure may not be limited thereto. The light blocking layer BM may be disposed on a surface of the window layer WN across a portion of the hole area HA and a portion of the display area DA adjacent to the hole area HA. Or, the light blocking layer BM may be disposed within the protective layer PL across a portion of the hole area HA and a portion of the display area DA adjacent to the hole area HA.

The second adhesive layer AM2 may overlap the light blocking layer BM. For example, the second adhesive layer AM2 may entirely overlap the light blocking layers BM. In an embodiment, a width of the second adhesive layer AM2 may be greater than a width of the light blocking layer BM. However, the present disclosure may not be limited thereto.

In an embodiment, a width W2 of the light blocking layer BM, depicted in FIG. 4, adjacent to the hole area HA may be smaller than a width W1 of the light blocking layer BM, depicted in FIG. 2, adjacent to the peripheral area PA. However, the present disclosure may not be limited thereto.

At least one second hole H2 extending through the display panel PN in the third direction DR3 may be defined in the display panel PN. At least one third hole H3 extending through the protective film PF in the third direction DR3 may be defined in the protective film PF. At least one fourth hole H4 extending through the third adhesive layer AM3 in the third direction DR3 may be defined in the third adhesive layer AM3. At least one fifth hole H5 extending through the support member SUP in the third direction DR3 may be defined in the support member SUP.

In the hole area HA, the first, second, third, fourth, and fifth holes H1, H2, H3, H4, and H5 may be connected to define a hole H. The hole area HA may be an area through which light is transmitted through the hole H. The component CAM may be disposed below the support member SUP corresponding to the hole area HA. The component CAM may receive the light passing through the hole area HA.

In an embodiment, examples of the component CAM may include a camera module, a face recognition sensor module, a pupil recognition sensor module, an acceleration sensor module, a proximity sensor module, an infrared sensor module, or an illumination sensor module. The camera module may be a module that captures (or recognizes) an image of an object positioned in front of the display device DD. The facial recognition sensor module may be a module that detects the user's face. The pupil recognition sensor module may be a module that detects the user's pupils. The acceleration sensor module and the geomagnetic sensor module may be modules that determine movement of the display device. The proximity sensor module and the infrared sensor module may be modules that detect proximity to the front of the display device. The illumination sensor module may be a module that measures the degree of external brightness.

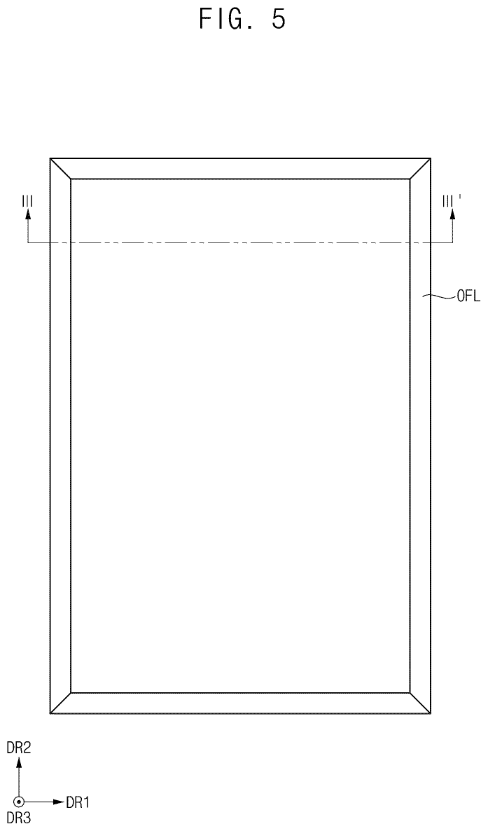

As described above, the display device according to embodiments of the present disclosure may include the first adhesive layer AM1 including the third contact surface S3 inclined toward the optical functional layer OFL in the direction toward the boundary T1 of the hole H and the second adhesive layer AM2 disposed between the first adhesive layer AM1 and the window layer WN, and including the fourth contact surface S4 inclined toward the window layer WN in the direction from the boundary T2 of the hole H. Accordingly, in the hole area HA, by filling a gap between the first adhesive layer AM1 and the window layer WN with the second adhesive layer AM2, the bonding strength between the window layer WN and the optical functional layer OFL may be improved. Accordingly, the durability of the display device DD may be improved. FIGS. 5-21 depict cross-sectional views illustrating method of manufacturing the display device of FIG. 1.

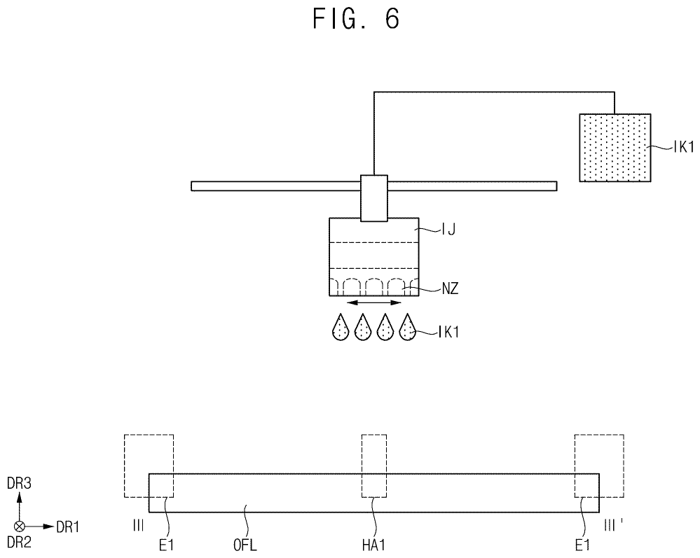

FIG. 5 is a plan view illustrating a process before the first adhesive layer (e.g., the first adhesive layer AM1 of FIG. 2) is applied on the optical functional layer OFL. FIG. 6 is a cross-sectional view illustrating a process of applying a first adhesive material IK1 to a cross-section of the optical functional layer OFL taken along a line III-III′ of FIG. 5.

Referring to FIGS. 5 and 6, the optical functional layer OFL may define a first area E1 positioned at an outermost portion of the optical functional layer OFL and a first hole area HA1 positioned at the center of the optical functional layer OFL. The first area E1 of the optical functional layer OFL may be an area where the first adhesive layer has an inclined surface (e.g., the first contact surface S1 of FIG. 2) is formed. The first hole area HA1 of the optical functional layer OFL may be an area where an inclined surface of the first adhesive layer (e.g., the third contact surface S3 of FIG. 4) is formed.

The first adhesive material IK1 may be sprayed toward the optical functional layer OFL through a nozzle NZ of an inkjet device IJ. The sprayed first adhesive material IK1 may be entirely applied on the optical function layer OFL. In an embodiment, the first adhesive material IK1 may include an optically clear adhesive resin (OCR). However, the present disclosure may not be limited therto.

In an embodiment, a viscosity of the first adhesive material IK1 may be about 50 cP or less. For example, a viscosity of the first adhesive material IK1 may be about 20 cP or less. Accordingly, the first adhesive material IK1 may be applied in a uniform amount throughout the optical function layer OFL. The first adhesive material IK1 may have a substantially uniform thickness on the optical functional layer OFL except around the first area E1 and the first hole area HA1.

In an embodiment, a thixotropic index (T1) of the first adhesive material IK1 may be about 1.5 or less. For example, the thixotropic index of the first adhesive material IK1 may be about 1 or less. The thixotropic index may satisfy an equation 1 below.

$$Thixotropic index = η0 \text{.5} / η5 \text{.0} , \qquad [ Equation 1 ]$$

where η0.5 refers to a viscosity at 25° C., 0.5 rpm and η5.0 refers to a viscosity at 25° C., 5.0 rpm.

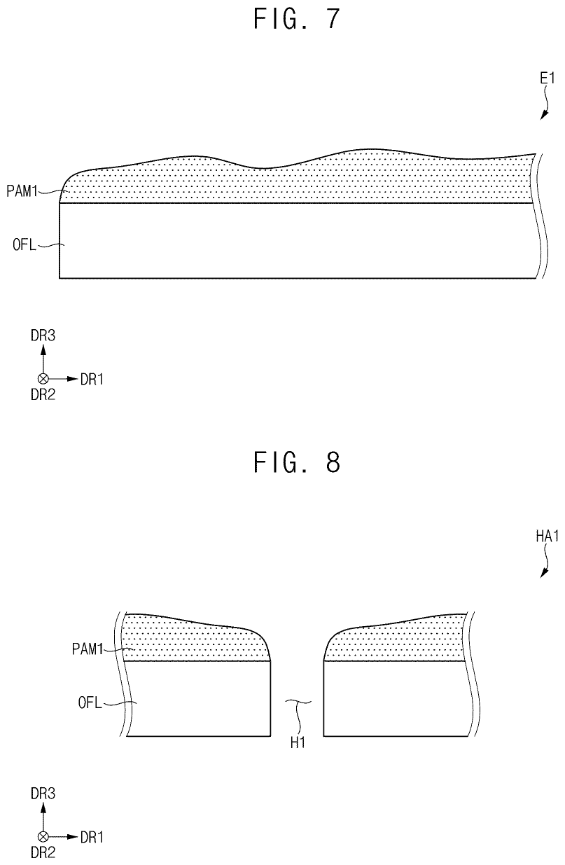

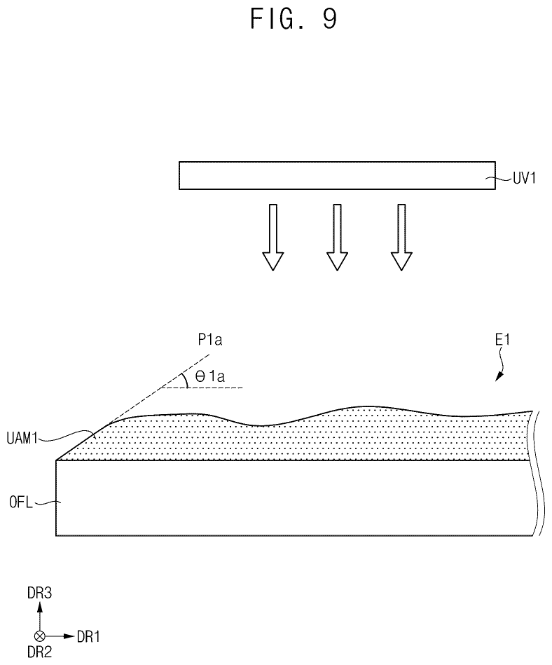

FIG. 7 is an enlarged cross-sectional view of a portion of the first area E1 of FIG. 6. FIG. 8 is an enlarged cross-sectional view of the first hole area HA1 of FIG. 6.

Referring to FIGS. 7 and 8, a first preliminary adhesive layer PAM1 may be formed on the optical functional layer OFL. The first preliminary adhesive layer PAM1 may be formed by applying the first adhesive material (e.g., the first adhesive material IK1) on the optical functional layer OFL. In an embodiment, in the first area E1, the first preliminary adhesive layer PAM1 may have a decreasing thickness toward the end of the optical functional layer OFL.

A first hole H1 extending through the optical function layer OFL in the third direction DR3 may be defined in the first hole area HA1. The first preliminary adhesive layer PAM1 may be formed on the optical functional layer OFL around the first hole H1 and along the boundary of the first hole H1. In other words, the first preliminary adhesive layer PAM1 may be cut off by the first hole H1 in a cross-sectional view. In an embodiment, the first preliminary adhesive layer PAM1 may have a decreasing thickness toward the boundary of the first hole H1.

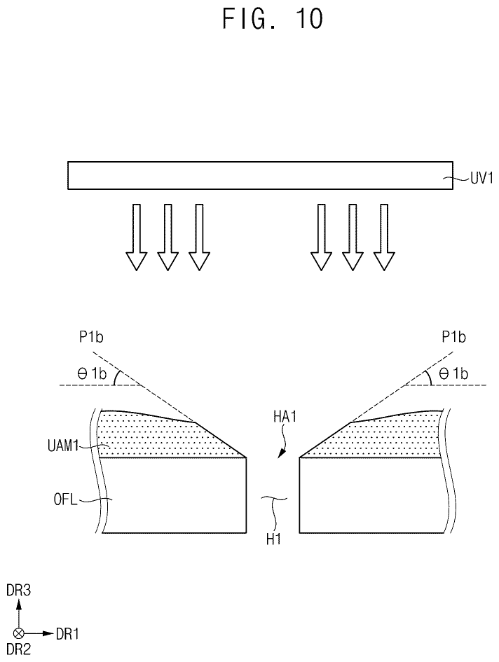

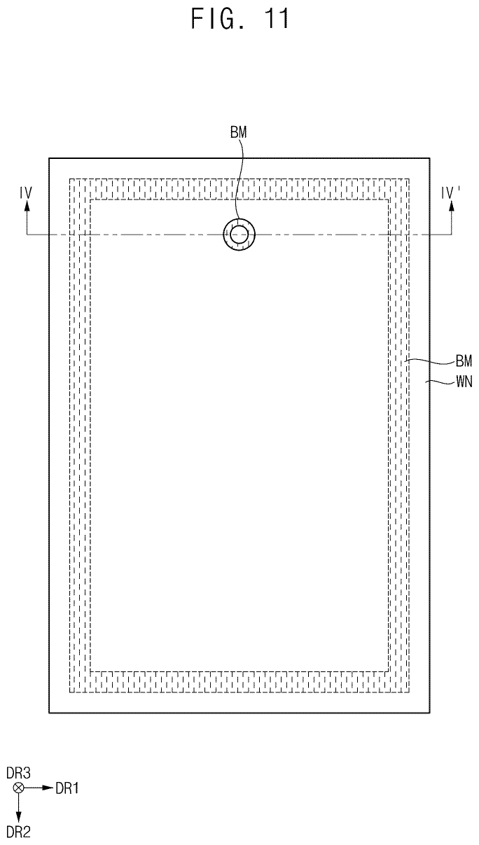

Referring to FIGS. 9 and 10, the first preliminary adhesive layer (e.g., the preliminary adhesive layer PAM1 of FIG. 7) may be cured to form a first cured layer UAM1. For example, the first cured layer UAM1 may be formed by irradiating the first preliminary adhesive layer with a first ultraviolet ray UV1.

The first cured layer UAM1 may include a first inclined surface P1a in the first area E1. The first inclined surface P1a may be formed on the end of the optical function layer OFL. The first inclined surface P1a may form a first inclined angle θ1a with an upper surface of the optical functional layer OFL.

In an embodiment, the first inclined surface P1a may have a decreasing thickness as it progresses from the center of the optical function layer OFL to the end of the optical function layer OFL in the first area E1. The first inclined surface P1a may extend with a slope away from the end of the optical functional layer OFL from a point where the first inclined surface P1a meets the optical functional layer OFL.

The first cured layer UAM1 may include a first inclined surface P1b positioned on both sides of the first hole H1 in the first hole area HA1. The first inclined surface P1b may be formed on the boundary of the first hole H1. The first inclined surface P1b may form a first inclined angle θ1b with the upper surface of the optical function layer OFL.

In an embodiment, the first cured layer UAM1 may include the first inclined surface P1b whose thickness decreases as it progresses toward the boundary of the first hole H1. In an embodiment, the first inclined angles θ1a and θ1b may have the same angle. However, the present disclosure may not be limited thereto. The first inclined angles θ1a and θ1b may have different angles.

In an embodiment, a modulus of the first cured layer UAM1 may be about 0.05 MPa or less. For example, a modulus of the first cured layer UAM1 may be about 0.02 MPa to about 0.05 MPa.

In an embodiment, a viscosity of the first cured layer UAM1 may be about 5,000,000 cP or less. For example, a viscosity of the first cured layer UAM1 may be about 500,000 cP to about 5,000,000 cP.

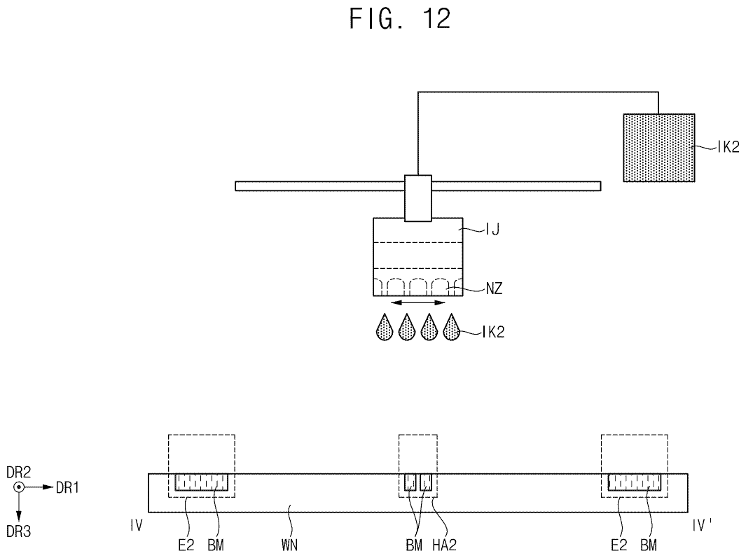

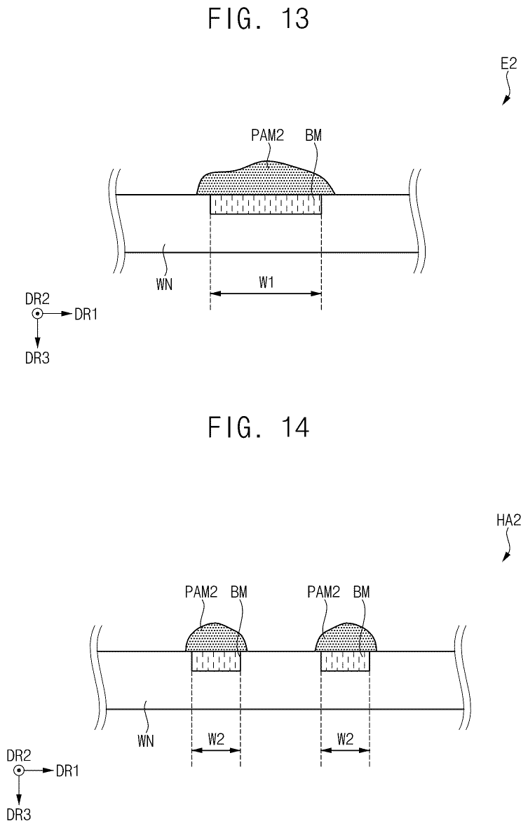

FIG. 11 is a plan view illustrating a process before the second adhesive layer (e.g., the second adhesive layer AM2 of FIG. 2) is applied on the window layer WN. FIG. 12 is a cross-sectional view illustrating a process of applying the second adhesive material IK2 to a cross-section of the window layer WN taken along a line IV-IV′ of FIG. 11.

Referring to FIGS. 11 and 12, a light blocking layer BM may be formed on the window layer WN. The window layer WN may include a second area E2 corresponding to the first area (e.g., the first area E1 of FIG. 6) and a second hole area HA2 corresponding to the first hole area (e.g., the first hole area of FIG. 6). The light blocking layer BM may be positioned in the second area E2 and the hole area HA.

The second area E2 of the window layer WN may be an area where the second adhesive layer has an inclined surface (e.g., the second contact surface S2 in FIG. 2). The second hole area HA2 of the window layer WN may be an area where an inclined surface of the second adhesive layer (e.g., the fourth contact surface S4 in FIG. 4) is formed.

The second adhesive material IK2 may be sprayed toward the window layer WN through the nozzle NZ of the inkjet device IJ. The sprayed second adhesive material IK2 may be applied on the second area E2 and the second hole area HA2 of the window layer WN. For example, the second adhesive material IK2 may be applied on the light blocking layer BM positioned in the second area E2 and the second hole area HA2.

In an embodiment, the second adhesive material IK2 and the first adhesive material IK1 may include a same material. For example, the second adhesive material IK2 may include an optically clear adhesive resin (OCR). However, the present disclosure may not be limited thereto.

In an embodiment, a viscosity of the second adhesive material IK2 may be substantially the same as a viscosity of the first adhesive material. Thus, the viscosity of the second adhesive material IK2 may be about 50 cP or less. For example, the viscosity of the second adhesive material IK2 may be about 20 cP or less. However, the present disclosure may not be limited thereto, and the viscosity of the second adhesive material IK2 may have a different value from the viscosity of the first adhesive material.

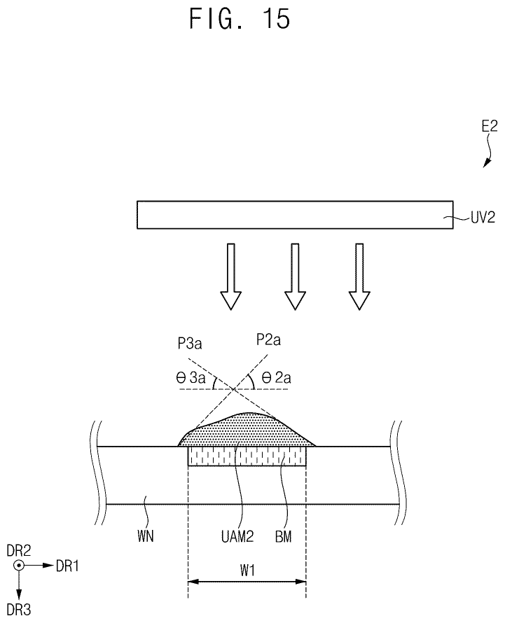

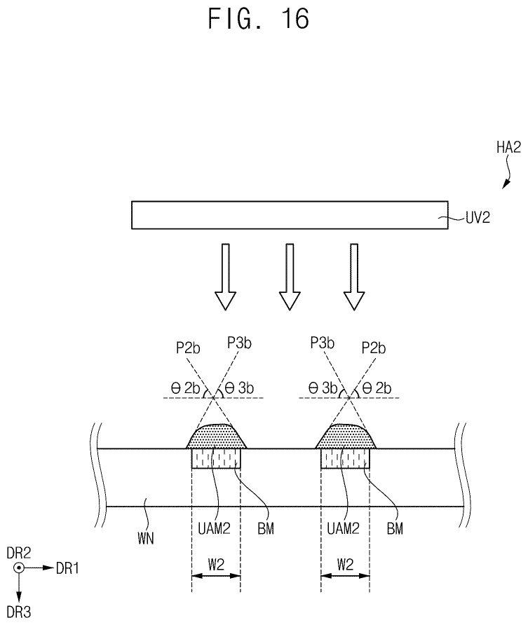

Referring to FIGS. 13 and 14, the second preliminary adhesive layer PAM2 may be formed on the window layer WN. For example, the second preliminary adhesive layer PAM2 may entirely overlap light blocking layer BM formed on the window layer WN in both the second area E2 and the second hole area HA2. In an embodiment, a width of the second preliminary adhesive layer PAM2 may be greater than a width of the light blocking layer BM. However, the present disclosure may not be limited thereto.

In an embodiment, a width W1 of the light blocking layer BM positioned in the second area E2 in the first direction DR1 is greater than a width W2 of the light blocking layer BM positioned in the second hole HA2 in the first direction DR1. Accordingly, a width of the second preliminary adhesive layer PAM2 positioned in the second area E2 in the first direction DR1 is greater than a width of the second preliminary adhesive layer PAM2 positioned in the second hole area HA2 in the first direction DR1. However, the present disclosure may not be limited thereto.

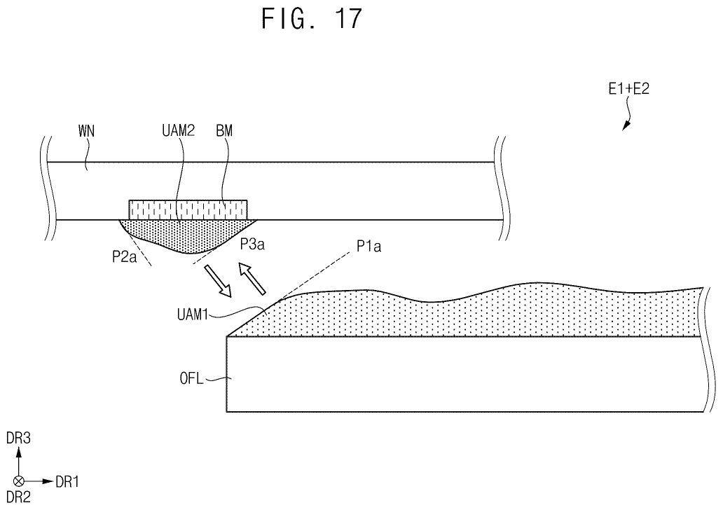

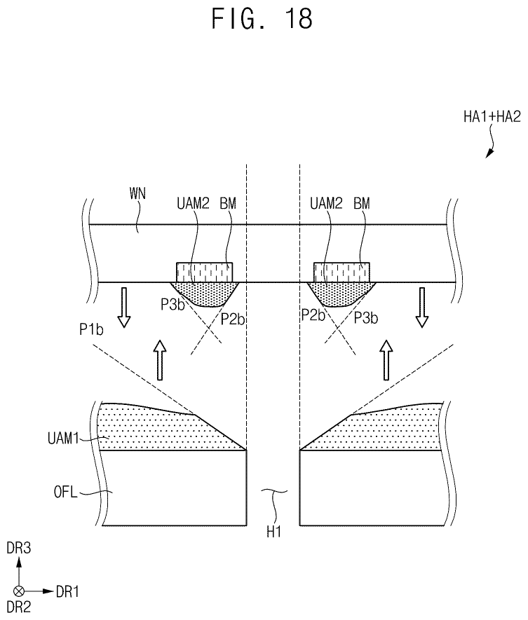

Referring to FIGS. 15 and 16, the second preliminary adhesive layer (e.g., the second preliminary adhesive layer PAM2 of FIG. 13) may be cured to form the second cured layer UAM2. For example, the second cured layer UAM2 may be formed by irradiating a second ultraviolet ray UV2 to the second preliminary adhesive layer PAM2.

The second cured layer UAM2 may have a second inclined surface P2a and a third inclined surface P3a in the second area E2. The second inclined surface P2a may form a second inclined angle θ2a with an upper surface of the window layer WN. The third inclined surface P3a may form a third inclined angle θ3a with the upper surface of the window layer WN. A virtual line extending along the second inclined surface P2a and a virtual line extending along the third inclined surface P3a may intersect with each other on the light blocking layer BM. For example, the second cured layer UAM2 may have a convex shape in the third direction DR3.

The second cured layer UAM2 may include a second inclined surface P2b and a third inclined surface P3b in the second hole area HA2. The second inclined surface P2b may form a second inclined angle θ2b with the upper surface of the window layer WN. The third inclined surface P3b may form a third inclined angle θ3b with the upper surface of the window layer WN.

The third inclined surface P3b of the second hole area HA2 may be a surface in contact with the first inclined surface (e.g., the first inclined surface P1b of FIG. 10).

In an embodiment, the second inclined angles θ2a and θ2b may have the same angle. However, the present disclosure may not be limited thereto. The second inclination angles θ2a and θ2b may have different angles.

In an embodiment, the third inclined angles θ3a and θ3b may have the same angle. However, the present disclosure may not be limited thereto. The second inclination angles θ3a and θ3b may have different angles.

In an embodiment, the first inclined angle θ1a in the first area E1 may be smaller than the second inclined angle θ2a in the second area E2. The first inclined angle θ1b in the first hole area HA1 may be smaller than the second inclined angle θ2b in the second hole area HA2.

In an embodiment, a modulus of the second cured layer UAM2 may be smaller than the modulus of the first cured layer (e.g., the first cured layer UAM1 of FIGS. 9 and 10). The modulus of the second cured layer UAM2 may be about 0.02 MPa or less. For example, the modulus of the second cured layer UAM2 may be about 0.01 MPa to about 0.02 MPa.

In an embodiment, a viscosity of the second cured layer UAM2 may be lower than the viscosity of the first cured layer. The viscosity of the second cured layer UAM2 may be 1,000,000 cP or less. For example, the viscosity of the second cured layer UAM2 may be 300,000 cP to 1,000,000 cP.

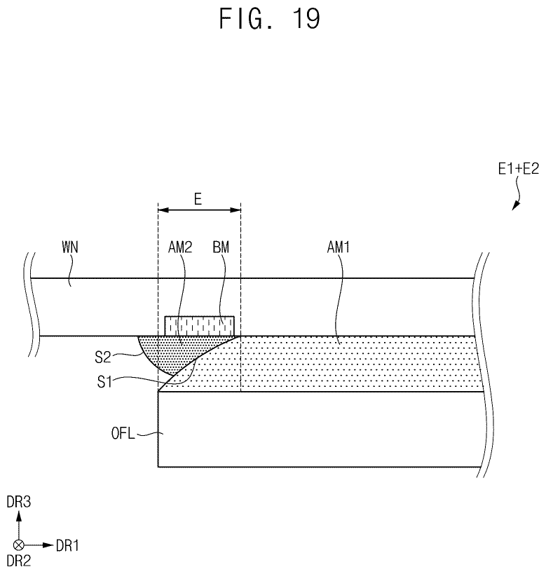

Referring to FIGS. 17 and 18, the optical function layer OFL and the window layer WN may be bonded to each other so that the first cured layer UAM1 and the second cured layer UAM2 are in contact with each other. For example, the optical functional layer OFL and the window layer WN may be bonded to each other so that the first area E1 of the optical functional layer OFL and the second area E2 of the window layer WN overlap each other. For example, the first inclined surface P1a of the first cured layer UAM1 and the third inclined surface P3a of the second cured layer UAM2 may be in contact with each other.

The optical functional layer OFL and the window layer WN may be bonded so that the first hole area HA1 of the optical functional layer OFL and the second hole area HA2 of the window layer WN overlap each other. For example, the first inclined surface P1b of the first cured layer UAM1 and the third inclined surface P3b of the second cured layer UAM2 may be contact with each other. In the first hole area HA1 and the second hole area HA2, the boundary of the first hole H1 may be adjacent to the light blocking layer BM.

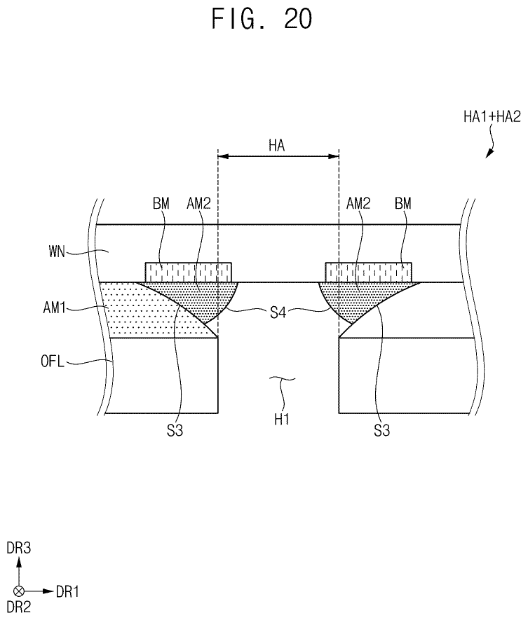

Referring to FIGS. 19 and 20, during a process of bonding the optical functional layer OFL and the window layer WN, the shape and structure of each of the first cured layer UAM1 and the second cured layer UAM2 may be changed. Through the process of bonding the optical functional layer OFL and the window layer WN, the first cured layer UAM1 may form the first adhesive layer AM1. In other words, the shape and structure of the first cured layer UAM1 may change to the shape and structure of the first adhesive layer AM1, as described above with reference to FIG. 2. In addition, through the process of bonding the optical functional layer OFL and the window layer WN, the second cured layer UAM2 may form the second adhesive layer AM2. In other words, the shape and structure of the second cured layer UAM2 may change to the shape and structure of the second adhesive layer AM2, as described above with reference to FIG. 2. As a result, the optical functional layer OFL and the window layer WN may be bonded by the first adhesive layer AM1 and the second adhesive layer AM2.

In the first area and the second area, the first inclined surface and the third inclined surface (e.g., the first inclined surface P1a and the third inclined surface P3a of FIG. 17) contact each other, and the first contact surface S1 of the first adhesive layer AM1 may be formed. In the first hole area and the second hole area, the first inclined surface and the third inclined surface (e.g. the first inclined surface P1b and the third inclined surface P3b of FIG. 18) contact each other to form the third contact surface S3 of the first adhesive layer AM1 may be formed.

In the first area and the second area, a second inclined surface (e.g., the second inclined surface P2a of FIG. 17) may correspond to the second contact surface S2 of the second adhesive layer AM2. In the first hole area and the second hole area, a second inclined surface (e.g., the second inclined surface P2b in FIG. 18) may correspond to the fourth contact surface S4 of the second adhesive layer AM2.

As described above, according to embodiments of the present disclosure, a method of manufacturing the display device DD comprises applying the first adhesive material IK1 onto the optical functional layer OFL, forming the first cured layer UAM1 by curing the first adhesive material IK1, applying the second adhesive material IK2 onto the window layer WN, forming the second cured layer UAM2 by curing the second adhesive material IK2, bonding the optical functional layer OFL and the window layer WN by bringing the first curing layer UAM1 and the second curing layer UAM2 into contact with each other. Accordingly, reducing a number of curing processes for the first adhesive layer AM1 may facilitate the bonding between the window layer WN and the optical functional layer OFL.

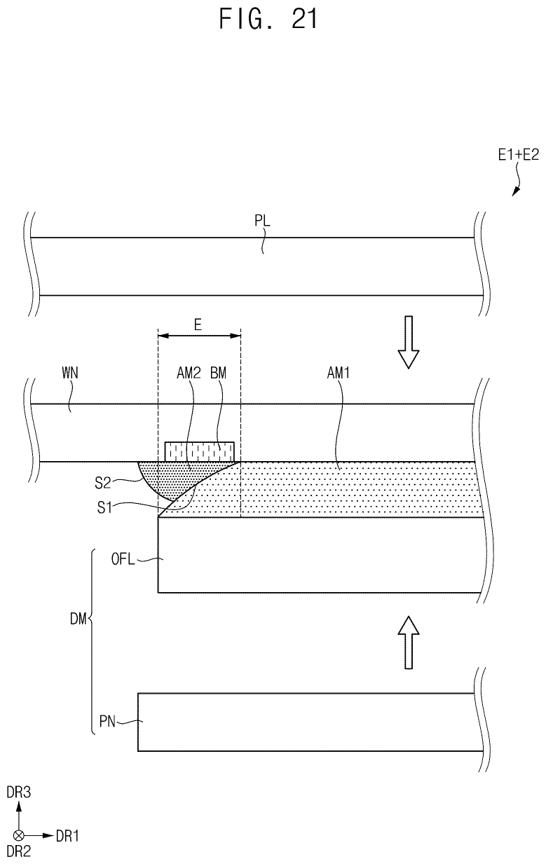

Referring to FIG. 21, the display panel PN may be formed under the optical function layer OFL. In addition, the protective layer PL may be formed on the window layer WN. Accordingly, the display device DD of FIG. 1 may be manufactured.

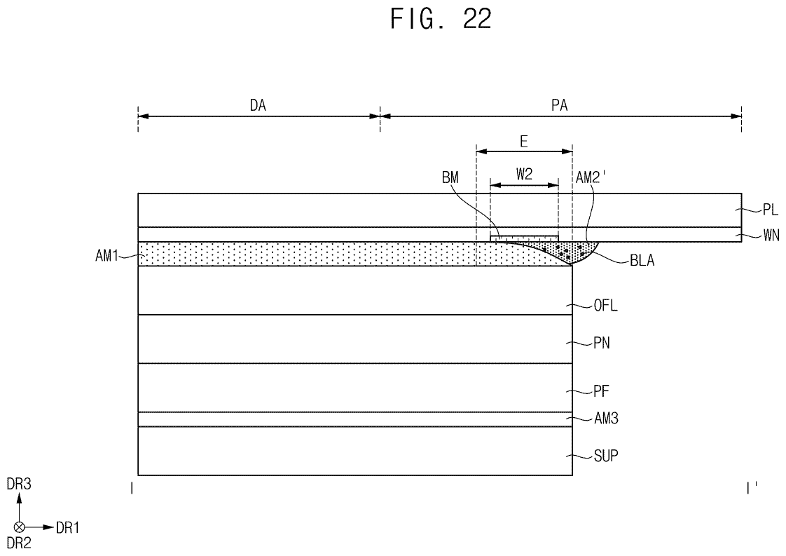

FIG. 22 is a cross-sectional view illustrating another example of the display device taken along a line I-I′ of FIG. 1.

The display device of FIG. 22 may have substantially the same components as the display device of FIG. 2 except for a second adhesive layer AM2′. Hereinafter, the same or duplicate descriptions mentioned above with reference to FIG. 2 will be omitted or simplified.

The second adhesive layer AM2′ may include a different material from the first adhesive layer AM1. In an embodiment, the second adhesive layer AM2′ may include a light blocking material BLA. For example, the light blocking material BLA may include a carbon black, a titanium nitride oxide, a titanium black, an aluminum zinc oxide (AZO), or the like. These may be used alone or in combination. In addition, the light blocking material BLA may further include an organic pigment. The organic pigment may include a phthalocyanine, a quinoneimine, a nitro quinoline, a carbonyl, a metyne, or the like. These may be used alone or in combination with each other. Accordingly, the second adhesive layer AM2′ may further reduce external light incident on the display device.

In an embodiment, the optical density (OD) of the light blocking material BLA may be about 2 to about 5. For example, the optical density of the light blocking material BLA may be about 5.

In an embodiment, the thickness of the second adhesive layer AM2′ may be about 50 μm or less. For example, the thickness of the second adhesive layer AM2′ may be about 30 μm to about 50 μm.

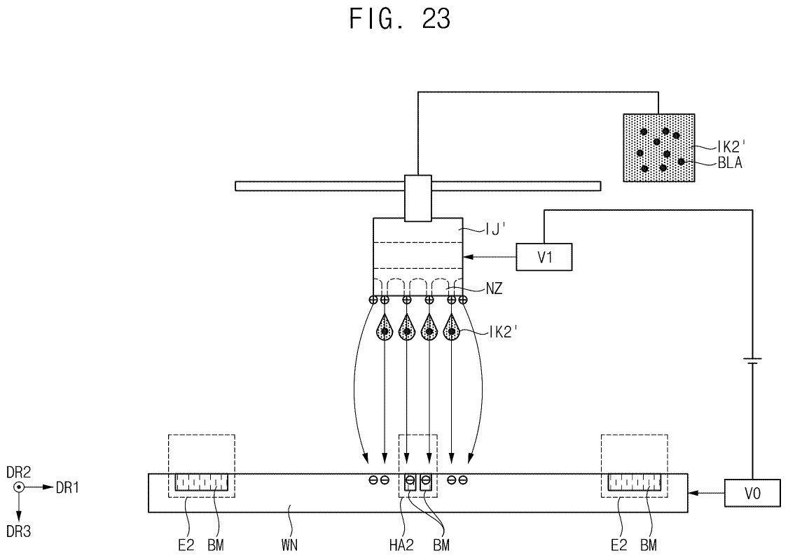

FIG. 23 is a cross-sectional view illustrating a method of manufacturing the second adhesive layer of FIG. 22.

The method of manufacturing the display device of FIG. 22 may be substantially the same as the method of manufacturing the display device of FIG. 2, except for the method of manufacturing the second adhesive layer AM2′. Therefore, the same or duplicate descriptions mentioned above with reference to FIGS. 5 to 21 will be omitted or simplified. A method of manufacturing the second adhesive layer (AM2′) of FIG. 22 will be described below with reference to FIG. 23.

Referring to FIG. 23, a second adhesive material IK2′ may include a light blocking material BLA. The second adhesive material IK2′ forming the second adhesive layer (e.g., the second adhesive layer AM2′ of FIG. 22) may be sprayed onto the window layer WN through an inkjet device IJ′. For example, the second adhesive material IK2′ may be sprayed on the window layer WN using an electro hydrodynamic (EHD) dispensing method.

After the second adhesive material IK2′ is sprayed on the window layer WN to form a second preliminary adhesive layer, the second preliminary adhesive layer may be cured to form a second cured layer. Accordingly, when forming the second cured layer from the second adhesive material IK2′, a viscosity of the second cured layer may be smaller than a viscosity of the second cured layer UAM2 of FIG. 15. Accordingly, the shape of the second cured layer may be more easily maintained, and the bonding strength between the window layer WN and the optical functional layer (e.g., the optical functional layer OFL of FIG. 22) may be further improved.

An electric field may be generated by the first voltage V1, which is a high voltage applied around the nozzle NZ, and the second voltage V2, which is a ground voltage applied around the window layer WN. Accordingly, the second adhesive material IK2′ including the light blocking material BLA may be sprayed into the second area E2 and the second hole area HA2 by the electric field.

In an embodiment, a thixotropic index of the second adhesive material IK2′ may be greater than the thixotropic index of the first adhesive material (e.g., the first adhesive material IK1 in FIG. 6). The thixotropic index of the second adhesive material IK2′ may be about 1.5 or more. For example, the thixotropic index of the second adhesive material IK2′ may be about 4.0 or more. More particularly, the thixotropic index of the second adhesive material IK2′ may be from about 4.0 to about 5.0. In an embodiment, the viscosity of the second cured layer may be about 300,000 cP or less.

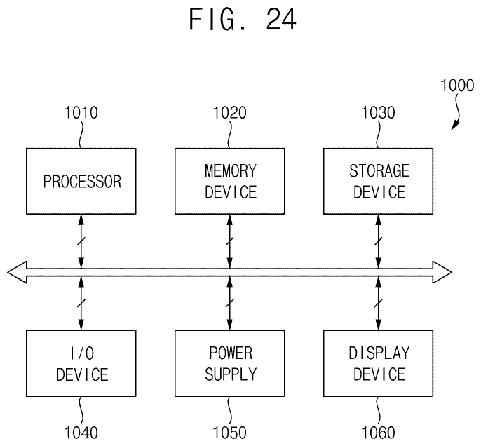

FIG. 24 is a block diagram illustrating an electronic device according to an embodiment.

Referring to FIG. 24, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device DD of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like. The power supply 1050 may provide power for operations of the electronic device 1000.

The power supply 1050 may provide power to the display device 1060. The display device 1060 may be coupled to other components via the buses or other communication links. In an embodiment, the display device 1060 may be included in the I/O device 1040.

The embodiments of the present disclosure may be applied to a display device and an electronic device including the same. For example, the electronic device having the display device according to the present disclosure may include a computer, a laptop, a mobile phone, a smartphone, a smart pad, a PMP, a PDA, an MP3 player, or the like.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a display panel including at least one light-emitting element;
an optical functional layer disposed on the display panel;
a window layer disposed on the optical functional layer;
a first adhesive layer disposed between the optical functional layer and the window layer, and including a first contact surface inclined toward the optical functional layer in a direction from a center of the optical functional layer to an edge of the optical functional layer; and
a second adhesive layer disposed between the first adhesive layer and the window layer, and including a second contact surface inclined toward the window layer in a direction from the edge of the optical functional layer toward an outer edge of the display device.

2. The display device of claim 1, wherein the second contact surface of the second adhesive layer extends from the first contact surface of the first adhesive layer to the window layer and passes over the end of the optical functional layer.

3. The display device of claim 1, wherein at least one hole extending through the optical functional layer is defined in the optical functional layer,
the first adhesive layer further includes a third contact surface inclined toward the optical functional layer in a direction toward a boundary of the hole, and
the second adhesive layer further includes a fourth contact surface inclined toward the window layer in a direction from the boundary of the hole.

4. The display device of claim 3, wherein the fourth contact surface of the second adhesive layer extends from the third contact surface to the window layer and passes over the boundary of the hole.

5. The display device of claim 3, wherein the third contact surface and the fourth contact surface are adjacent to the hole.

6. The display device of claim 1, wherein the first adhesive layer and the second adhesive layer include a same material.

7. The display device of claim 1, wherein the first adhesive layer includes a material different from the second adhesive layer.

8. The display device of claim 7, wherein the second adhesive layer includes a light blocking material.

9. The display device of claim 8, wherein a thickness of the second adhesive layer is about 50 μm or less.

10. The display device of claim 1, further comprising:
a light blocking layer overlapping the second adhesive layer, and
wherein a width of the second adhesive layer is greater than a width of the light blocking layer.

11. A method of manufacturing a display device, the method comprising:
applying a first adhesive material on an optical functional layer;
forming a first cured layer including a first inclined surface on the optical functional layer by curing the first adhesive material;
applying a second adhesive material on a window layer;
forming a second cured layer including a second inclined surface on the window layer by curing the second adhesive material; and
bonding the optical functional layer and the window layer by bringing the first cured layer and the second cured layer into contact with each other.

12. The method of claim 11, wherein each of the first adhesive material and the second adhesive material has a thixotropic index calculated using an equation:
thixotropic index=η0.5/η5.0, where η0.5 refers to a viscosity at 25° C., 0.5 rpm and η5.0 refers to a viscosity at 25° C., 5.0 rpm, and
wherein a thixotropic index of the first adhesive material is smaller than a thixotropic index of the second adhesive material.

13. The method of claim 12, wherein the thixotropic index of the first adhesive material is about 1.5 or less, and the thixotropic index of the second adhesive material is about 4.0 or more.

14. The method of claim 11, wherein the second adhesive material includes a light blocking material, and
the applying the second adhesive material is performed by an electro hydrodynamic dispensing process.

15. The method of claim 11, wherein a modulus of the first cured layer is larger than a modulus of the second cured layer.

16. The method of claim 15, wherein the modulus of the first cured layer is about 0.05 Mpa or less, and
the modulus of the second cured layer is about 0.02 Mpa or less.

17. The method of claim 11, wherein a viscosity of the first cured layer is smaller than a viscosity of the second cured layer.

18. The method of claim 17, wherein a viscosity of the first adhesive material is about 50 cP or less,
the viscosity of the first cured layer is about 5,000,000 cP or less, and
the viscosity of the second cured layer is about 1,000,000 cP or less.

19. The method of claim 11, wherein a first inclined angle between the first inclined surface and the optical functional layer is smaller than a second inclined angle between the second inclined surface and the window layer.

20. The method of claim 11, the method further comprising:
forming a light blocking layer by applying a light blocking material on the window layer, and
wherein in the applying the second adhesive material, the second adhesive material is applied to a position where the light blocking layer is formed.

21. An electronic device comprising:
a display device; and
a power supply configured to provide power to the display device,
wherein the display device comprises:
a display panel including at least one light-emitting element;
an optical functional layer disposed on the display panel;
a window layer disposed on the optical functional layer;
a first adhesive layer disposed between the optical functional layer and the window layer, and including a first contact surface inclined toward the optical functional layer in a direction from a center of the optical functional layer to an edge of the optical functional layer; and
a second adhesive layer disposed between the first adhesive layer and the window layer, and including a second contact surface inclined toward the window layer in a direction from the edge of the optical functional layer toward an outer edge of the display device.
